(19) United States
(12) Patent Application Publication
(10) Pub. No.: US 2012/0248589 A1
(43) Pub. Date: Oct. 4, 2012

(54) LEAD FRAME WITH COINED INNER LEADS

(75) Inventors: Jinquan WANG, Tianjin (CN); Yuan YUAN, Austin, TX (US)

(73) Assignee: FREESCALE SEMICONDUCTOR, INC, Austin, TX (US)

(21) Appl. No.: 13/398,824

(22) Filed: Feb. 16, 2012

(30) Foreign Application Priority Data
Mar. 29, 2011 (CN) 201110097375.0

(51) Int. Cl. H01L 23/495

(52) U.S. Cl. 257/667; 257/676; 257/E23.037; 257/E23.031

(57) ABSTRACT

A lead frame used in semiconductor packaging has an outer dam bar and inner leads that extend away from the dam bar. The inner leads have distal ends and tips at the distal ends. Each inner lead has a coined area on a first major surface at the distal end and spaced from the tip. The coined area and the spacing of the coined area from the tip form a shoulder structure. The coined area is configured to receive one end of a bond wire that interconnects the inner lead with a wire bond pad of a semiconductor die. The shoulder structure creates a molding compound locking mechanism to reduce shear stress and delamination in the lead bonding area.

### BACKGROUND OF THE INVENTION

The present invention relates generally to semiconductor packaging and more particularly to a lead frame for a semiconductor device.

Lead frame type semiconductor devices typically comprise a die bond pad, an integrated circuit or die that is attached to a surface of the die bond pad and one or more rows of leads that surround the die. The die is electrically connected to the leads with wires via a wire bonding process. The die, leads and wires are then covered with a plastic molding compound with ends or bottoms of the leads being exposed to allow for external electrical connection.

One problem with such devices is that the molding compound may not adhere well to the leads, in which case the molding compound can separate from one or more of the leads, especially when stresses are induced by temperature changes. This problem is known as delamination. The lead tip, which is the end of the lead closest to the die and where the bond wire is attached or bonded is a place of high internal stress and often is where delamination is initiated.

Lead frames usually are formed of Copper alloy and the bond wires are often formed of Gold. To promote the wire bonding, the lead tips often are coated with Silver. Unfortunately, the molding compound does not bond well with Silver, although it does bond well with Copper. The delamination that may occur between the molding compound and the Silver coating can cause wire bonding failure. In addition, because the Copper lead and molding compound have different coefficients of thermal expansion (CTE), shear stress often occurs near the lead tip. This shear stress can also cause the wire bond connection to fail.

FIG. 1 is a cross-sectional view of an integrated circuit (IC or die) 10 attached to a die bond pad 12. A wire bond pad 15 of the die 10 is connected to a lead 14 with a wire 16. As shown in the drawing, the wire 14 is attached at one end of the lead 14. This end of the lead 14 is sometimes coined such that the lead 14 includes a recess 18 in which the bond wire 16 is attached. The coined recess 18 is coated or plated with Silver to allow for a good wire to lead bond. However, as discussed above, the lead tip or area of the recess 18 is a place of high stress and since molding compound does not adhere well to Silver, delamination may occur at this location, which can lead to failure of the wire bond.

Thus, it would be advantageous to have a lead frame with inner leads that are less susceptible to delamination.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged cross-sectional side view of a conventional bond wire connecting a wire bond pad of an integrated circuit die to an inner lead of a lead frame;

FIG. 2 is an enlarged top plan view of a lead frame in accordance with an embodiment of the present invention;

FIG. 3 is an enlarged cross-sectional side view of a bond wire connecting a wire bond pad of an integrated circuit die to an inner lead of a lead frame in accordance with an embodiment of the present invention; and

FIG. 4 is an enlarged cross-sectional side view of a portion of an integrated circuit device including a bond wire connecting an integrated circuit die to an inner lead in accordance with an embodiment of the present invention.

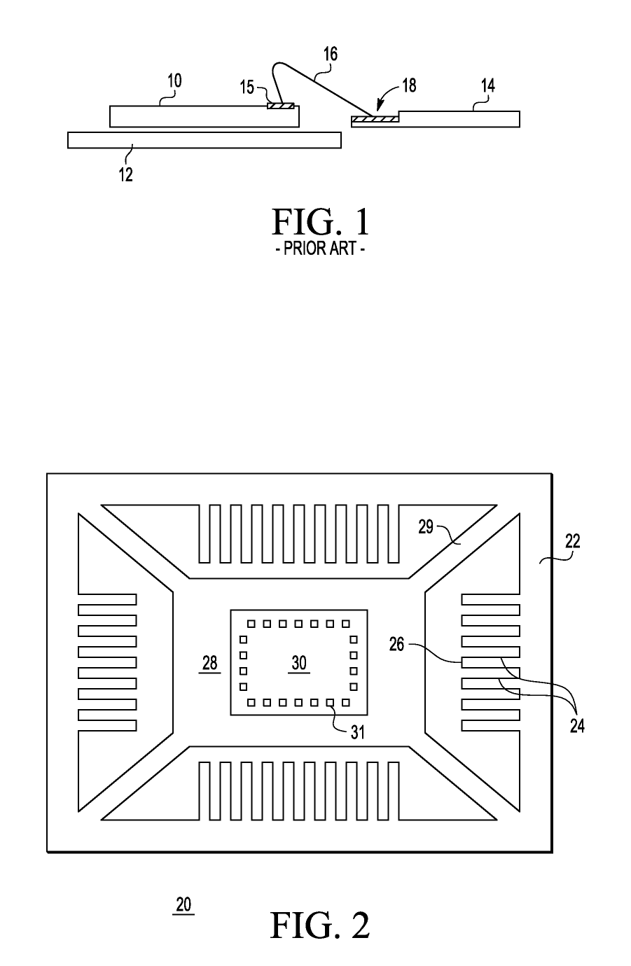

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention.

In one embodiment, the present invention provides a lead frame for a semiconductor device. The lead frame includes a generally rectangular outer dam bar and a plurality of inner leads extending from the dam bar. The inner leads are disposed within the lead frame and near a die bond pad or substrate configured to receive an integrated circuit die. Distal ends of the inner leads are the ends of the leads that are spaced from the dam bar. The distal ends have a tip. A first major surface of each inner lead includes a coined area at the distal end. The coined area is spaced from the tip by a predetermined distance. The spacing of the coined area from the tip forms a shoulder at the tip. An inner surface of the coined area may be plated with Silver or another metal or alloy that allows for a strong bond with a bond wire, while the shoulder area remains bare so that a strong bond is made with a molding compound used to cover the integrated circuit die, the bond wire, and the inner lead.

In another embodiment, the present invention provides an integrated circuit device including a semiconductor die having a plurality of die wire bond pads formed on a surface thereof and a plurality of inner leads spaced from and surrounding the semiconductor die. The inner leads each have a tip at a distal end that is proximate to the semiconductor die. A first major surface of the inner leads includes a coined area that is spaced from the distal end by a predetermined distance. A plurality of bond wires connects the die wire bond pads with the coined areas of respective ones of the inner leads. One end of each of the bond wires is attached or bonded to the coined areas and the other ends of the bond wires are attached or bonded to respective ones of the die wire bond pads. An encapsulation material covers the die wire bond pads, the bond wires and the coined areas. In one embodiment, the inner leads are formed from Copper, the coined areas are plated with Silver and the bond wires are formed from Gold.

Referring now to FIG. 2, an enlarged plan view of a lead frame 20 in accordance with an embodiment of the present invention is shown. The lead frame 20 includes a generally rectangular outer dam bar 22 and a plurality of inner leads 24. The inner leads 24 extend from the dam bar 22 inwardly, towards a center of the lead frame 20, with distal ends 26 of the leads 24 being distant from the dam bar 22. The lead frame 20 may have an empty space at the center or alternatively a die bond pad 28, as shown in FIG. 2. The die bond pad 28 may be attached to the dam bar 22 with tie bars 29. The die bond pad 28 is sized and shaped to receive a semiconductor integrated circuit die 30, which may be attached to the die bond pad 28 in a known manner. The integrated circuit die 30 has a plurality of wire bond pads 31 on an active surface thereof.

The lead frame 20 is formed of conductive metal with the dam bar 22, inner leads 24, die bond pad 28, and tie bar 29 being formed by cutting, stamping, punching or etching. In one embodiment, the lead frame 20 is formed from Copper. Lead frames are generally well known to those of skill in the art so further description as well as discussion of variations in lead frame types is not necessary for a complete understanding of the present invention. Suffice it to say that those of skill in the art will understand that the present invention can be applied to various types of lead frames.

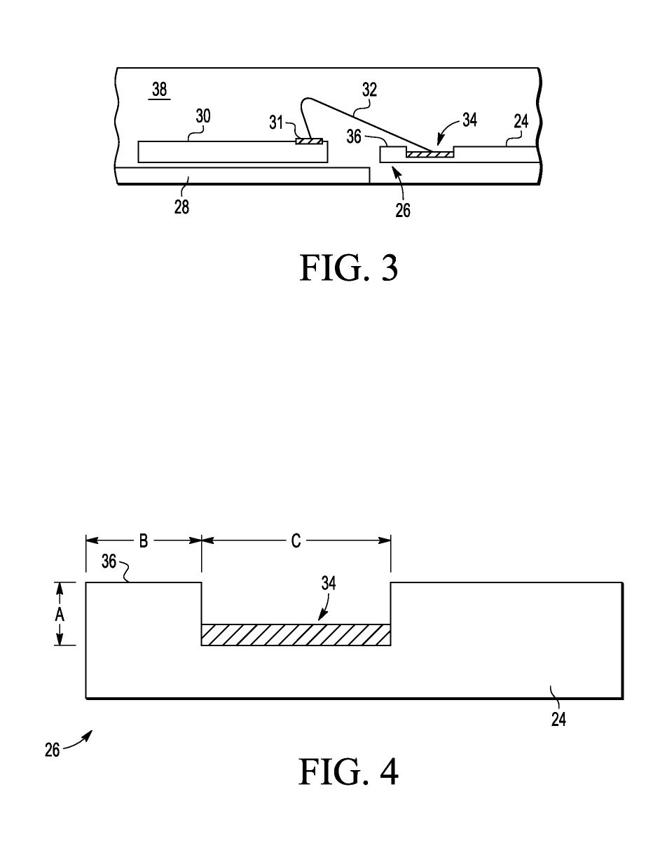

Referring now to FIG. 3, an enlarged, cross-sectional side view of a portion of a semiconductor device formed using the lead frame 20 is shown in which a semiconductor die 30 is attached to a top or first major surface of the die bond pad 28. The semiconductor die 30 may be attached to the die bond pad 28 with epoxy or other adhesive materials or solder as is known to those of skill in the art. FIG. 3 also shows an inner lead 24 having a distal end 26 that is proximate to the die bond pad 28 and the semiconductor die 30. A bond wire 32 interconnects a wire bond pad 31 of the die 30 with the inner lead 24. The bond wire 32 may be attached to the die wire bond pad 31 with a ball bond and to the inner lead 24 with a stitch or wedge bond using commercially available wire bonding equipment. The bond wire 32 electrically connects the semiconductor die 30 with the inner lead 24. The bond wire 32 may be any electrically conductive wire, such as Gold, Copper or Aluminum wire, and either bare or coated. In one embodiment, the bond wire 32 comprises 0.6 mil to 1.3 mil Gold wire as is commonly used in semiconductor packaging.

In the embodiment shown, the inner lead 24 includes a coined area 34 on a top or first major surface at the distal end 26. The coined area 34 is spaced from the distal end 26 by a predetermined distance such that a shoulder 36 is formed at the distal end 26. The bond wire 32 is attached or bonded to the coined area 34 of the inner lead 24. In order to form a good bond between, for example a Gold bond wire and a Copper inner lead 24, at least a portion of an inner surface of the coined area 34 may be plated with a metal or metal alloy. In one embodiment, the coined area 34 is plated with Silver. The coined area 34 may be formed by any suitable method such as cutting, stamping or etching.

As shown in FIG. 3, the die 30, wire 32 and at least a portion of the inner lead 24 are covered with a molding compound 38 such as a plastic or epoxy compound, as are known to those of skill in the art. Various methods may be used to form the molding compound 38 over the die 30, wire 32 and inner lead 24 such as transfer molding, injection molding, glob top dispensing, etc. In order to allow for good adhesion of the molding compound 38 to the inner lead 24 at the distal end 26 of the inner lead 24, while the coined area 34 is plated, the shoulder 36 preferably remains bare. Although in some embodiments, the shoulder 36 could be coated with a material that enhances adhesion between the inner lead 24 and the molding compound 38. An inner lead 24 with the shoulder 36 causes the wire bond site to be spaced from the distal end 26 of the inner lead 24, which moves the wire bond site to an area of lower shear stress so there is less likelihood of a bond being damaged. The shoulder 36, since it is not coated with Silver, also provides for better adhesion of the molding compound to the distal end 26 of the inner lead 24 so there is less likelihood of delamination occurring at the distal end 26 of the inner lead 24.

FIG. 4 is an enlarged side view of an inner lead 24 in accordance with one embodiment of the invention. In this embodiment, the inner lead 24 is coined to a depth A, where A is in the range of about 0.03 mm to about 0.12 mm, or up to half of the thickness of the inner lead 24 depending on the gauge of the inner leads 24 of the lead frame 20. Further, the coined area 34 is spaced from a tip of the distal end 26, or put another way, the shoulder 36 has a length B, where B is in the range of about 0.20 mm to about 2.00 mm. The coined area 34 is sized so that wire bonds may be readily formed therein. In one embodiment of the invention, the coined area 34 has a length C, where C has a length of about 0.50 mm+/−0.25 mm. To reduce the contact area between the molding compound 38 and the Silver coating, a shorter length coined area 34 is preferred as long as it is permitted by the manufacturing process. The shoulder 36 and the coined area 34 create a mold lock mechanism to reduce molding compound shear stress, which is significantly large in the lead tip area. Better adhesion between the molding compound and shoulder also provides an anchor that reduces the pulling stress on the wire bond. As will be understood by those of skill in the art, the present invention is generally suitable for bonding wires formed of various materials, such as Gold, Copper and Aluminum.

As is evident from the foregoing discussion, the present invention provides a lead frame with coined inner leads that allows reliable lead to mold compound attachment, which reduces the chance of delamination occurring at the ends of the inner leads.

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as described in the claims.

1. A lead frame for a semiconductor device, the lead frame comprising:
a generally rectangular outer dam bar; and
a plurality of inner leads extending from the dam bar, the inner leads having distal ends spaced from the dam bar, each of the distal ends having a tip, wherein a first major surface of each inner lead includes a coined area at said distal end, said coined area being spaced from said tip by a predetermined distance, and wherein spacing said coined area from said distal end forms a shoulder area at said distal end.

2. The lead frame of claim 1, wherein said predetermined distance is between 0.20 mm and 2.0 mm from said tip.

3. The lead frame of claim 1, wherein said coined area has a depth of between 0.03 mm and 0.12 mm

4. The lead frame of claim 1, wherein said coined area has a depth of up to about half of a thickness of the inner lead.

5. The lead frame of claim 1, wherein said coined area is plated with a metal or metal alloy that allows for a strong bond with a bond wire.

6. The lead frame of claim 5, wherein the lead frame is formed of Copper, said coined area is plated with Silver, and the shoulder area of the inner lead is unplated.

7. The lead frame of claim 1, further comprising a die bond pad located at a generally central area of the lead frame and within a perimeter formed by the dam bar and the inner leads, wherein the tips of the inner leads are spaced from the die bond pad.

8. The lead frame of claim 7, wherein the die bond pad is attached to the dam bar with a tie bar.

9. An integrated circuit device, comprising:
a semiconductor die having a plurality of die wire bond pads formed on a surface thereof;
a plurality of inner leads spaced from and surrounding said semiconductor die, said inner leads having a tip that is proximate to said semiconductor die, wherein a first major surface of said inner leads includes a coined area, said coined area being spaced from said tip by a predetermined distance, wherein spacing said coined areas from said tips forms shoulder areas on said inner leads;
a plurality of bond wires connecting the die wire bond pads with respective ones of said inner leads, wherein one end of each of said bond wires is attached to said coined areas and the other end of each of said bond wires is attached to a respective one of said die wire bond pads; and
an encapsulation material covering said die, said bond wires and said coined areas.

10. The integrated circuit device of claim 9, wherein said predetermined distance is between about 0.20 mm to 2.0 mm from said tip.

11. The integrated circuit device of claim 9, where said coined area has a depth of between 0.03 mm and 0.12 mm.

12. The integrated circuit device of claim 11, wherein said coined area is plated.

13. The integrated circuit device of claim 12, wherein the shoulder area of the inner lead is unplated.

14. The integrated circuit device of claim 9, wherein said inner leads are formed of Copper, the wires are formed of Gold and said coined area is plated with Silver.

15. The integrated circuit device of claim 9, further comprising a die bond pad upon which the semiconductor die is mounted.

16. A lead frame for a semiconductor device, the lead frame comprising:
a generally rectangular outer dam bar; and
a plurality of inner leads extending from the dam bar, the inner leads having distal ends spaced from the dam bar, each distal end having a tip, wherein the first major surface of each inner lead includes a coined area at said distal end, said coined area being spaced from said tip by a predetermined distance of between 0.20 mm and 2.00 mm, and having a depth of between 0.03 mm and 0.12 mm, and
wherein the lead frame is formed of Copper, said coined area is plated with Silver, and said inner lead tip is bare.
